(19) United States
(12) Patent Application Publication
(10) Pub. No.: US 2008/0265971 A1
(43) Pub. Date: Oct. 30, 2008

(54) Voltage level shift circuits

(75) Inventor: Jung-Yen Kuo, Yunlin County (TW)

Correspondence Address: Joe McKinney Muncy, PO Box 1364, Fairfax, VA, 22038-1364, US

(73) Assignee: PRINCETON TECHNOLOGY CORPORATION

(21) Appl. No.: 11/822,498

(22) Filed: Jul. 6, 2007

(30) Foreign Application Priority Data
Apr. 24, 2007 (TW) 096206511

(51) Int. Cl. H03L 5/00; H02P 8/00

(52) U.S. Cl. 327/333; 318/696

(57) ABSTRACT

A voltage level shift circuit has a plurality of input voltage sources, a reference voltage source, a voltage level shift unit, a stabilizing unit, a first output voltage terminal, and a second output voltage terminal. The input voltage sources provide a plurality of input voltages. The reference voltage source provides a reference voltage. The voltage level shift unit raises the input voltages to a level of the reference voltage. The stabilizing unit prevents power leakage and resulting abnormal voltage levels in the voltage level shift unit. The first output voltage terminal provides a first output voltage. The second output voltage terminal provides a second output voltage inverse to the first output voltage.

### BACKGROUND OF THE INVENTION

1. Field of the Invention

The invention relates to a voltage level shift circuit, and more particularly to a voltage level shift circuit applied in a step motor driving circuit.

2. Description of the Related Art

Typically, in a conventional step motor, an H bridge circuit drives the step motor to rotate in different directions and stop. As shown in FIG. 1, an H bridge circuit 1 comprises four metal oxide semiconductors (MOSs). The direction of rotation of a motor 15 is controlled by turning on the first MOS 11 and the third MOS or turning on the second MOS 12 and the fourth MOS 14. Input of voltage is required at the MOS gates to turn each MOS on or off. Because a different voltage is required for turning on each MOS, a different output voltage circuit controls each MOS. Thus, the gate of each MOS is coupled to an output voltage. Voltages from the output voltage circuits control the H bridge circuit to drive a step motor.

Each output voltage circuit has an input voltage insufficient to turn on a MOS. The output voltage circuit thus raises the input voltage to a sufficient value to turn on the MOS, thereby driving the H bridge circuit to operate.

Because a conventional H bridge circuit comprises four MOSs, a gate of each MOS is coupled to an output voltage circuit, and each MOS is turned on by a high level voltage output from the output voltage circuit, thus, a motor is driven. Four output voltage circuits are required, however, increasing cost. Moreover, if the voltages from the four output voltage circuits are not generated synchronously, the motor does not function normally. Thus, a driving step motor circuit capable of ameliorating the foregoing disadvantages is desirable.

### BRIEF SUMMARY OF THE INVENTION

Voltage level shift circuits are provided. An exemplary embodiment of a voltage level shift circuit comprises a plurality of input voltage sources, a reference voltage source, a voltage level shift unit, a stabilizing unit, a first output voltage terminal, and a second output voltage terminal. The input voltage sources provide a plurality of input voltages. The reference voltage source provides a reference voltage. The voltage level shift unit raises the input voltages to a level of the reference voltage. The stabilizing unit prevents power leakage and resulting abnormal voltage levels in the voltage level shift unit. The first output voltage terminal provides a first output voltage. The second output voltage terminal provides a second output voltage, inverse to the first output voltage.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a conventional H bridge circuit; and

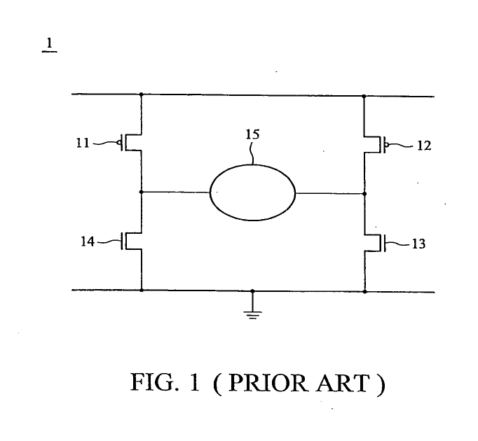

FIG. 2 shows an exemplary embodiment of a voltage level shift circuit.

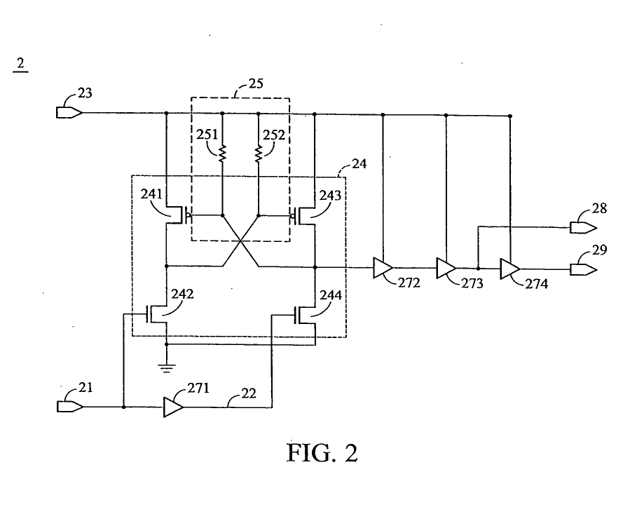

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

Voltage level shift circuits are provided. In an exemplary embodiment of a voltage level shift circuit in FIG. 24, a voltage level shift circuit 2 comprises a first input voltage source 21, a second input voltage source 22, a reference voltage source 23, a voltage level shift unit 24, a stabilizing unit 25, a ground 26, first to fourth inverters 271-274, a first output voltage terminal 28, and a second output voltage terminal 29.

The first input voltage source 21 is coupled to the first inverter 271 and provides an input voltage of 0V or 5V (low level or high level). The combination of the first input voltage source 21 and the inverter 271 serves as the second input voltage source 22. Because the first inverter 271 is coupled between the first input voltage source 21 and the second input voltage source 22, the input voltage from the first input voltage source 21, inverse to an input voltage from the second input voltage source22. For example, when the input voltage from the first input voltage source 21 is 5V, the second input voltage source 22 provides the input voltage with 0V, inverse to the input voltage of 5V.

The reference voltage source 23 is coupled to the voltage level shift unit 24 and provides a reference voltage with a level of 13V. The voltage level shift unit 24 comprises a first P-type metal oxide semiconductor (PMOS) 241, a first N-type metal oxide semiconductor (NMOS) 242, a second PMOS 243, and a second NMOS 244. The reference voltage source 23 is coupled to sources of the first and second PMOSs 241 and 243. The first input voltage source 21 is coupled to a gate of the first NMOS 242, and the second input voltage source 22 is coupled to a gate of the second NMOS 244. A gate of the first PMOS 241 is coupled to drains of the second PMOS 243 and the second NMOS 244. A gate of the second PMOS 243 is coupled to drains of the first PMOS 241 and the first NMOS 242. Through the operation of the voltage level shift unit 24, the levels of input voltages provided by the first and second input voltage sources 21 and 22 are raised to 13V, and the raised input voltages are output by the first and second output voltage terminals 28 and 29.

The stabilizing unit 25 comprises a first resistor 251 and a second resistor 252. The first resistor 251 is coupled between the reference voltage source 23 and the gate of the first PMOS 241. The second resistor 252 is coupled between the reference voltage source 23 and the gate of the second PMOS 243. When the voltage level shift unit 24 operates, the stabilizing unit 25 is capable of preventing power leakage and resulting unstable voltage levels in the voltage level shift unit 24, thus, the voltage level shift circuit 2 operates normally.

The second, third, and fourth inverters 272, 273, and 274 are serially coupled. An input terminal of the second inverter 272 is coupled to the gate of the first PMOS 241, and an output terminal thereof is coupled to an input terminal of the third inverter 273. An output terminal of the third inverter 273 is coupled to an input terminal of the fourth inverter 274. Control terminals of the second, third, and fourth inverters 272, 273, and 274 are coupled together to the reference voltage source 23. The second and third inverters 272 and 273 can amplify and stabilize the voltage raised by the voltage level shift unit 24.

The first output voltage terminal 28 is coupled to the output terminal of the third inverter 273, and the second output voltage terminal 29 is coupled to an output terminal of the fourth inverter 274. Because the fourth inverter 274 is coupled between the first output voltage terminal 28 and the second output voltage terminal 29, a voltage output by the first output voltage terminal 28 is inverse to a voltage output by the second output voltage terminal 29.

When the input voltage from the first input voltage source 21 is 5V, the second input voltage source 22 provides the input voltage with 0V, inverse to the input voltage of 5V. The reference voltage source 23 provides the constant reference voltage of 13V. Through the operation of the voltage level shift unit 24, a voltage output from the first output voltage terminal 28 is at a high level of 13V, and a voltage output from the second output voltage source 29 is at a low level of 0V due to the operation of the fourth inverter 274. When the input voltage from the first input voltage source 21 is 0V, the second input voltage source 22 provides the input voltage with 5V, the voltage output from the first output voltage terminal 28 is at the high level of 0V, and a voltage output from the second output voltage source 29 is at the low level of 13V.

According the foregoing description, the voltage level shift circuit provides a stabilizing unit to stabilize output voltages, preventing power leakage and abnormal voltage occurring during the voltage raising process. The voltage level shift circuit also outputs two inverse output voltages, thereby decreasing the number of voltage raising circuits required for driving a step motor.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A voltage level shift circuit, comprising:
a plurality of input voltage sources providing a plurality of input voltages;
a reference voltage source providing a reference voltage;
a voltage level shift unit raising the input voltages to a level of the reference voltage;
a stabilizing unit avoiding power leakage and resulting abnormal voltage levels in the voltage level shift unit;
a first output voltage terminal providing a first output voltage; and
a second output voltage terminal providing a second output voltage, wherein the first output voltage and the second output voltage are inverted.

2. The voltage level shift circuit as claimed in claim 1 further comprising a plurality of inverters changing phases of the first and second output voltages.

3. The voltage level shift circuit as claimed in claim 2, wherein one of the inverters is coupled between the first and second output voltage terminals.

4. The voltage level shift circuit as claimed in claim 1, the input voltage source comprises a first input voltage source and a second input voltage source providing inverse input voltages of 0V and 5V respectively.

5. The voltage level shift circuit as claimed in claim 1, wherein the voltage level shift unit comprises a first P-type metal oxide semiconductor (PMOS), a first N-type metal oxide semiconductor (NMOS), a second PMOS, and a second NMOS.

6. The voltage level shift circuit as claimed in claim 1, wherein the stabilizing unit comprises a plurality of resistors respectively coupled between the reference voltage source and a gate of the first PMOS and between the reference and a gate of the second PMOS.
